(19) United States
(12) Patent Application Publication
(10) Pub. No.: US 2019/0363241 A1
(43) Pub. Date: Nov. 28, 2019

(54) ULTRASONIC SENSING DEVICE, ELECTRONIC DEVICE USING SAME, AND METHOD FOR MAKING SAME

(71) Applicants: Interface Technology (ChengDu) Co., Ltd., Chengdu (CN); INTERFACE OPTOELECTRONICS (SHENZHEN) CO., LTD., Shenzhen (CN); GENERAL INTERFACE SOLUTION LIMITED, Zhunan (TW)

(72) Inventor: SHIH-CHIEH HUANG, Hsinchu (TW)

(21) Appl. No.: 16/147,802

(22) Filed: Sep. 30, 2018

(30) Foreign Application Priority Data
May 24, 2018 (CN) 201810506951.4

(51) Int. Cl. H01L 41/047; B06B 1/06; H01L 41/053; H01L 41/113; H01L 41/293; H01L 41/332; H01L 41/193

(52) U.S. Cl. CPC H01L 41/0472; B06B 1/0644; H01L 41/0477; H01L 41/053; G06K 9/0002; H01L 41/293; H01L 41/332; H01L 41/193; H01L 41/0475; H01L 41/1132

(57) ABSTRACT

An ultrasonic sensing device includes a circuit board, a piezoelectric material layer on the circuit board, a first electrode, and a second electrode on the circuit board. The circuit board is configured to dispose a circuit. The first electrode is formed on a surface of the piezoelectric material layer away from the circuit board. The piezoelectric material layer is between the first electrode and the second electrode; the first electrode has a thickness in a range from 0.005 μm to 1 μm.

### FIELD

The subject matter herein generally relates to an ultrasonic sensing device, an electronic device using the ultrasonic sensing device, and a method for making the ultrasonic sensing device.

### BACKGROUND

Nowadays, more and more electronic devices have functions of fingerprint identification. A conventional fingerprint identification device generally includes an ultrasonic sensing element that is capable of identifying a fingerprint of a finger placed on the fingerprint identification device. The ultrasonic sensing element generally includes a piezoelectric material layer and two electrodes formed on opposite sides of the piezoelectric material layer. Generally, at least one electrode is made of a layer of silver paste. However, when the layer of the silver paste has a thickness greater than 15 μm, a flexible circuit board may not be lapped directly on the surface of the silver paste electrode.

Therefore, there is room for improvement within the art.

### BRIEF DESCRIPTION OF THE DRAWINGS

Implementations of the present technology will now be described, by way of example only, with reference to the attached figures.

FIG. 1 is an isometric view of an ultrasonic sensing device according to an embodiment of the present disclosure.

FIG. 2 is a cross-sectional view of the ultrasonic sensing device of FIG. 1 along line II-II.

FIG. 3 is a plan view of an electronic device using the ultrasonic sensing device of FIG. 1.

FIG. 4 is a flowchart of a method for making an ultrasonic sensing device.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein may be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “coupled” is defined as connected, whether directly or indirectly through intervening components, and is not necessarily limited to physical connections. The connection can be such that the objects are permanently connected or releasably connected. The term “comprising” when utilized, means “including, but not necessarily limited to”; it specifically indicates open-ended inclusion or membership in the so-described combination, group, series, and the like.

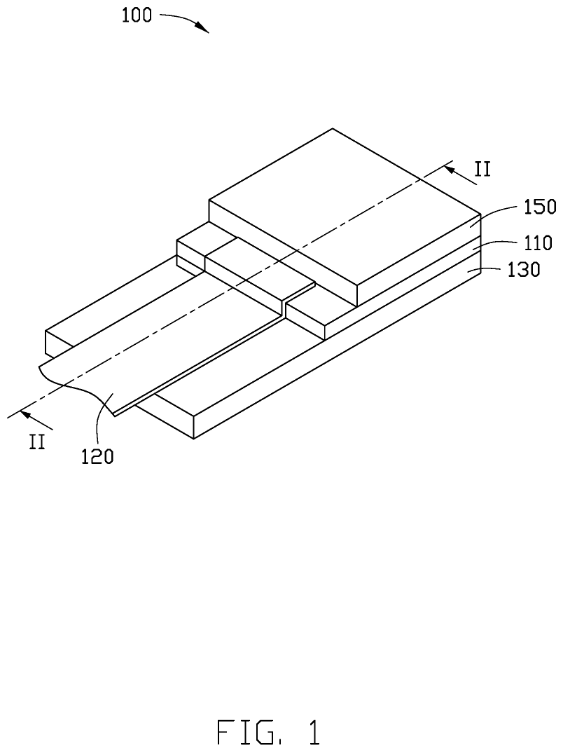

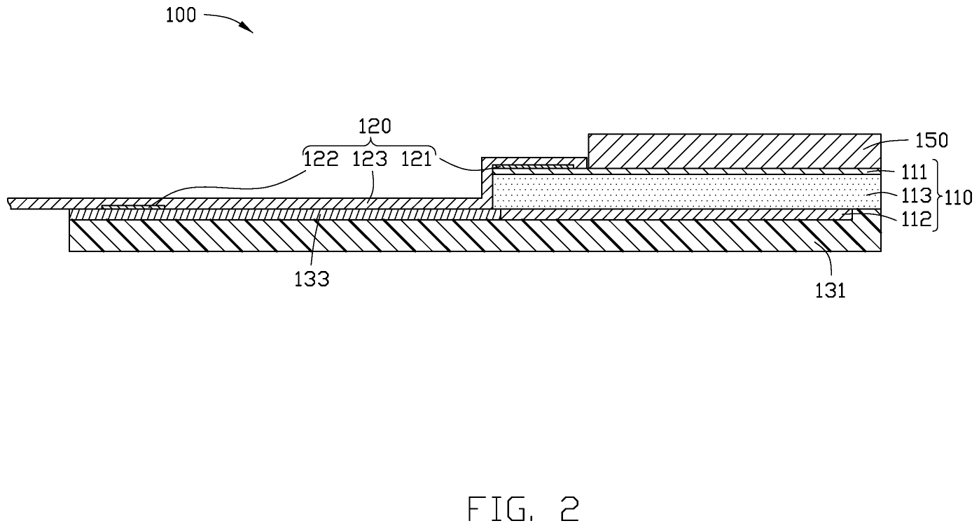

FIG. 1 and FIG. 2 illustrate an ultrasonic sensing device 100 according to an embodiment. The ultrasonic sensing device 100 includes a circuit board 130, an ultrasonic sensing unit 110, and a signal transmitting unit 120. The ultrasonic sensing device 100 can be used for identifying fingerprint.

As shown in FIG. 1 and FIG. 2, the ultrasonic sensing unit 110 is positioned on a surface of the circuit board 130 and partially covers the surface of the circuit board 130. The signal transmitting unit 120 is also positioned on the circuit board 130 and electrically coupled to the ultrasonic sensing unit 110 and the circuit board 130. The signal transmitting unit 120 is also electrically coupled to a controller (not shown), thus electrical signals can be transmitted between the controller and the ultrasonic sensing unit 110 and between the controller and the circuit board 130.

As shown in FIG. 2, the ultrasonic sensing unit 110 includes a piezoelectric material layer 113, a first electrode 111, and a second electrode 112. The piezoelectric material layer 113 is between the first electrode 111 and the second electrode 112. The second electrode 112 is formed on the circuit board 130 and between the circuit board 130 and the piezoelectric material layer 113. The first electrode 111 is formed on a side of the piezoelectric material layer 113 away from the circuit board 130. In this embodiment, the ultrasonic sensing unit 110 is configured to emit ultrasonic signals and receive the ultrasonic signals reflected back from objects (such as finger) in a time division method. When a voltage difference is formed between the first electrode 111 and the second electrode 112, the piezoelectric material layer 113 may vibrate and produce ultrasonic waves. When the piezoelectric material layer 113 receives reflected ultrasonic signals, the piezoelectric material layer 113 may vibrate and produce charges on its surface.

The circuit board 130 is configured to dispose a circuit layout. As shown in FIG. 2, the circuit board 130 includes a substrate 131 and a circuit 133 formed on the substrate 131. The second electrode 112 is formed on the substrate 131 and electrically coupled to the circuit 133. The circuit 133 is configured to receive and process the electrical signals from the ultrasonic sensing unit 110. In one embodiment, the circuit board 130 is a thin film transistor (TFT) board and the circuit 133 includes a plurality of TFTs. In other embodiment, the circuit board 130 is a printed circuit board.

As shown in FIG. 2, the signal transmitting unit 120 includes a flexible circuit board 123, a first connecting pad 121, and a second connecting pad 122. The first connecting pad 121 and the second connecting pad 122 are formed on the flexible circuit board 123. The flexible circuit board 123 covers a portion of the ultrasonic sensing unit 110, and in particular covers a portion of the first electrode 111, and extends to cover the circuit board 130. The first connecting pad 121 is in direct contact with the first electrode 111 and is between the flexible circuit board 123 and the first electrode 111, thus the flexible circuit board 123 is electrically coupled to the first electrode 111. The second connecting pad 122 is in direct contact with the second electrode 112 and between the flexible circuit board 123 and the circuit board 130, thus the flexible circuit board 123 is electrically coupled to the circuit board 130.

The first electrode 111 has a thickness in a range from 0.005 μm to 1 μm and a surface roughness Ra of less than or equal to 0.1. The first electrode 111 can be made by chemical vapor deposition (CVD) or physical vapor deposition (PVD). The first electrode 111 is made of a metal, such as copper (Cu), silver (Ag), platinum (Pt), or a metal alloy. The first electrode 111 can be used as a mask during etching process of the piezoelectric material layer 113. In one embodiment, the first electrode 111 is a copper layer having a thickness ranging from 0.005 μm to 1 μm and formed on a surface of the piezoelectric material layer 113 by vacuum evaporation, sputter coating, arc plasma plating, ion plating, or molecular beam epitaxy. The second electrode 112 may be made of indium tin oxide (ITO). The first electrode 111 has a relatively low thickness, thus the flexible circuit board 123 can be easily coupled to the first electrode 111 and the circuit board 130. The first electrode 111 has a relatively low surface roughness, thus reflection and refraction of the ultrasonic waves is less when passing through the first electrode 111, further improving the properties of the ultrasonic sensing device 100.

The ultrasonic sensing device 100 has a working cycle including a signal transmitting phase and a signal receiving phase. In the signal transmitting phase, the flexible circuit board 123 applies different voltages to the first electrode 111 and the circuit board 130, and the circuit board 130 applies the voltage signal to the second electrode 112. Thus, a voltage difference is formed on opposite sides of the piezoelectric material layer 113, and the piezoelectric material layer 113 vibrates and emits ultrasonic waves. In the signal receiving phase, the flexible circuit board 123 applies an operating voltage to the first electrode 111 and the second electrode 112, the piezoelectric material layer 113 receives the reflected ultrasonic wave and generates charges, and the second electrode 112 transmits the charges to the circuit 133 of the circuit board 130. The circuit 133 collects and analyzes charges current, and transmits the charges current to the controller through the flexible circuit board 123.

As shown in FIG. 1 and FIG. 2, the ultrasonic sensing device 100 further includes a cover 150. The cover 150 covers the ultrasonic sensing unit 110. In particular, the cover 150 covers a surface of the ultrasonic sensing unit 110 away from the circuit board 130. The cover 150 is configured to protect the ultrasonic sensing unit 110. External object, such as a finger, can directly touch a surface of the cover 150 away from the circuit board 130.

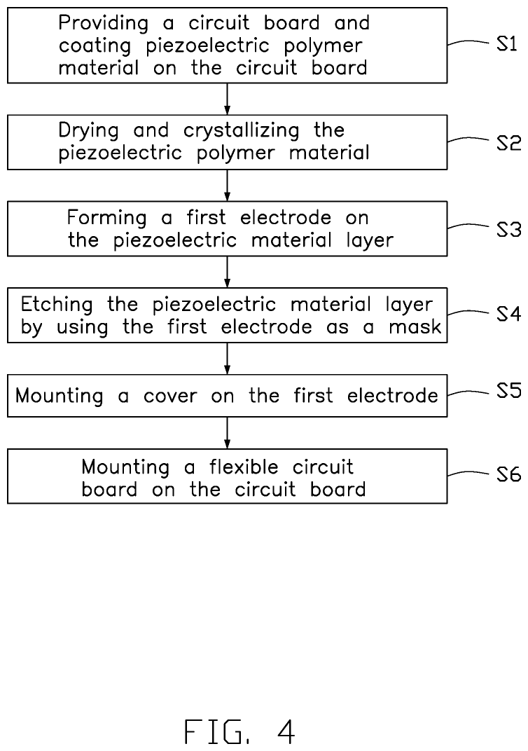

FIG. 4 illustrates a flowchart of one embodiment of a method for making the ultrasonic sensing device 100. The example method is provided by way of example, as there are a variety of ways to carry out the method. Each block shown in FIG. 4 represents one or more processes, methods, or subroutines, carried out in the exemplary method. Furthermore, the illustrated order of blocks is by example only and the order of the blocks can change. The exemplary method can begin at block S1 according to the present disclosure. Depending on the embodiment, additional steps can be added, others removed, and the ordering of the steps can be changed.

At block S1, a circuit board is provided and piezoelectric polymer material is coated on a surface of the circuit board.

The circuit board 130 includes a substrate 131 and a circuit 133 formed on the substrate 131. A second electrode 112 is formed on the substrate 131 and electrically coupled to the circuit 133. Before coating the piezoelectric polymer material, the circuit board 130 is cleaned and dried. The piezoelectric polymer material can be coated by a conventional coating process, such as spin coating, spraying, and dipping.

At block S2, the piezoelectric polymer material is dried and crystallized to form a piezoelectric material layer.

The piezoelectric polymer material applied on the circuit board 130 is dried to remove liquid solvent and form a solid layer, annealed to crystallize the piezoelectric material, and corona polarization treated. The piezoelectric material layer completely covers the second electrode 112.

At block S3, a first electrode is formed on a surface of the piezoelectric material layer away from the circuit board.

The first electrode 111 can be made by chemical vapor deposition (CVD) or physical vapor deposition (PVD). The first electrode 111 is made of a metal, such as copper (Cu), silver (Ag), platinum (Pt), or a metal alloy. The first electrode 111 has a thickness in a range from 0.005 μm to 1 μm and a surface roughness Ra of less than or equal to 0.1.

At block S4, the piezoelectric material layer is etched to form a piezoelectric layer by using the first electrode as a mask. Before etching, the piezoelectric material layer may not have a desired shape and size. The piezoelectric layer after the etching process may have a desired shape and size, and completely covers the second electrode 112.

At block S5, a cover is mounted to cover the first electrode. The cover covers a side of the first electrode away from the circuit board.

At block S6, a flexible circuit board is mounted to electrically couple to the first electrode and the circuit.

In one embodiment, the flexible circuit board is electrically coupled to the first electrode by one connecting pad and electrically coupled to the circuit by another connecting pad.

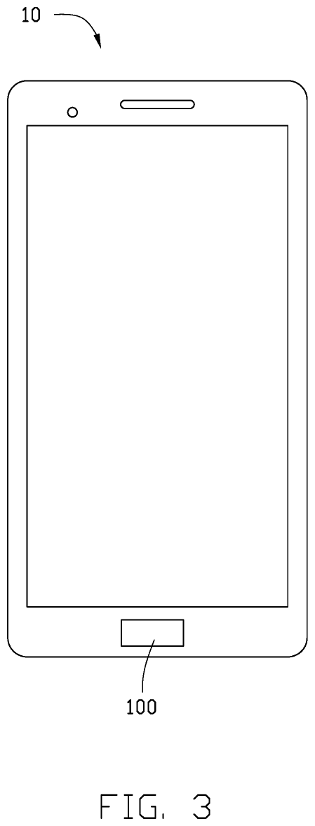

FIG. 3 illustrates an electronic device 10 having the ultrasonic sensing device 100. In this embodiment, the electronic device 10 is a mobile phone and the ultrasonic sensing device 100 is mounted under a home button. In other embodiment, the ultrasonic sensing device 100 may be mounted on a side surface or a back surface of the electronic device 10. The electronic device 10 is not limited to be a mobile phone, but can be other conventional electronic device, such as a personal computer, a smart home appliance, an industrial controller, or the like. The ultrasonic sensing device 100 can be used for, but is not limited to, fingerprint information collection, identity authentication, and unlocking.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. An ultrasonic sensing device comprising:
a circuit board configured to dispose a circuit;
a piezoelectric material layer disposed on the circuit board;
a first electrode formed on a surface of the piezoelectric material layer away from the circuit board;
a second electrode formed on the circuit board and electrically coupled to the circuit,
wherein the piezoelectric material layer is between the first electrode and the second electrode; the first electrode has a thickness in a range from 0.005 μm to 1 μm.

2. The ultrasonic sensing device of claim 1, wherein a surface roughness Ra of the first electrode is less than or equal to 0.1.

3. The ultrasonic sensing device of claim 1, wherein the first electrode is made of a metal or an alloy.

4. The ultrasonic sensing device of claim 1, further comprising a flexible circuit board, wherein the flexible circuit board is electrically coupled to the first electrode and the circuit of the circuit board.

5. The ultrasonic sensing device of claim 4, wherein the flexible circuit board partially covers the first electrode and extends to cover the circuit board.

6. The ultrasonic sensing device of claim 5, further comprising a first connecting pad and a second connecting pad, wherein the first connecting pad is between the first electrode and the flexible circuit board to electrically couple the first electrode to the flexible circuit board; and the second connecting pad is between the circuit and the flexible circuit board to electrically couple the circuit to the flexible circuit board.

7. The ultrasonic sensing device of claim 1, further comprising a cover on the first electrode, wherein the cover covers a side of the first electrode away from the circuit board.

8. An electronic device comprising an ultrasonic sensing device,
the ultrasonic sensing device comprising:
a circuit board configured to dispose a circuit layout;
a piezoelectric material layer on the circuit board;
a first electrode formed on a surface of the piezoelectric material layer away from the circuit board;
a second electrode formed on the circuit board and electrically coupled to the circuit,
wherein the piezoelectric material layer is between the first electrode and the second electrode; the first electrode has a thickness in a range from 0.005 μm to 1 μm.

9. The electronic device of claim 8, wherein a surface roughness Ra of the first electrode is less than or equal to 0.1.

10. The electronic device of claim 8, wherein the first electrode is made of a metal or an alloy.

11. The electronic device of claim 8, further comprising a flexible circuit board, wherein the flexible circuit board is electrically coupled to the first electrode and the circuit of the circuit board.

12. The electronic device of claim 11, wherein the flexible circuit board partially covers the first electrode and extends to cover the circuit board.

13. The electronic device of claim 11, further comprising a first connecting pad and a second connecting pad, wherein the first connecting pad is between the first electrode and the flexible circuit board to electrically couple the first electrode to the flexible circuit board; and the second connecting pad is between the circuit and the flexible circuit board to electrically couple the circuit to the flexible circuit board.

14. The electronic device of claim 12, further comprising a cover on the first electrode, wherein the cover covers a side of the first electrode away from the circuit board.

15. A method for making an ultrasonic sensing device, comprising:
providing a circuit board and forming a piezoelectric material layer on a surface of the circuit board;
forming a first electrode on a surface of the piezoelectric material layer; and
etching the piezoelectric material layer to form a piezoelectric layer by using the first electrode as a mask.

16. The method of claim 15, wherein the step of providing the circuit board comprises providing the circuit board having a circuit.

17. The method of claim 15, wherein the step of forming the first electrode comprises forming the first electrode by a chemical vapor deposition or a physical vapor deposition method to control a thickness of the first electrode to be in a range from 0.005 μm to 1 μm.

18. The method of claim 15, further comprising: mounting a flexible circuit board on the circuit board to electrically couple to the first electrode and the circuit; and mounting a cover to cover the first electrode.

19. The method of claim 15, wherein forming the piezoelectric material layer comprises:
coating piezoelectric polymer material on the circuit board; and
drying and crystallizing the piezoelectric polymer material.
